(19) United States
(12) Patent Application Publication
(10) Pub. No.: US 2015/0280835 A1
(43) Pub. Date: Oct. 1, 2015

(54) OPTICAL INTERCONNECTION DEVICE

(71) Applicant: V TECHNOLOGY CO., LTD., Yokohama-shi, Kanagawa (JP)

(72) Inventors: Koichi Kajiyama, Kanagawa (JP); Toshimichi Nasukawa, Kanagawa (JP); Masayasu Kanao, Kanagawa (JP); Shin Ishikawa, Kanagawa (JP)

(73) Assignee: V TECHNOLOGY CO., LTD., Kanagawa (JP)

(21) Appl. No.: 14/441,498

(22) PCT Filed: Oct. 3, 2013
(86) PCT No.: PCT/JP2013/076923

§ 371 Date: May 7, 2015

(30) Foreign Application Priority Data
Nov. 8, 2012 (JP) 2012-246685

(51) Int. Cl. H04B 10/80; H01L 31/167

(52) U.S. Cl. CPC H04B 10/803; H01L 31/167

(57) ABSTRACT

An optical interconnection device for transmitting and receiving an optical signal between a plurality of laminated semiconductor substrates. The optical interconnection device has a plurality of light emitting elements or a plurality of light receiving elements arranged in one of the semiconductor substrates that have pn junction parts using the semiconductor substrate as a common semiconductor layer. The light emitting element and the light receiving element, which form a pair and which transmit and receive an optical signal between the different semiconductor substrates, emit and receive light at a common wavelength.

### CROSS-REFERENCE TO RELATED APPLICATIONS

This application claims the benefit of International Application PCT/JP2013/076923, filed Oct. 3, 2013 and Japanese Patent Application JP2012-246685 filed Nov. 8, 2012, both of which are incorporated herein by reference in their entirety.

### TECHNICAL FIELD

The present invention generally relates to an optical interconnection device capable of achieving intra-chip optical interconnection.

### RELATED ART

The optical interconnection is widely available in the field of long-distance signal transmission using an optical fiber based on the utilization of characteristics such as high-speed, wide-bandwidth transmission, superior noise immunity, and a fine diameter of a cable. On the other hand, in order to further increase the information processing speed in the information processing device, extremely short distance optical interconnection between boards, chips, or in a chip is necessary, and a technology development for this has been advanced currently.

The three-dimensional packaging technology of laminating semiconductor chips in order to perform high-density mounting of semiconductor chips has been proposed in recent years. The intra-chip optical interconnection has been focused on as a technology of achieving signal transmission among this laminated semiconductor chips without any connection via a conductive wire or connection using an optical fiber. The conventional art described in Patent Literature 1 discloses laminating a plurality of optical transmission substrates to transmit and receive an optical signal between a light emitting element provided on one substrate and a light receiving element provided on another substrate.

### RELATED ART LITERATURE

### Patent Literature

Patent Literature 1: Japanese Patent Application Publication No. 2000-277794

### SUMMARY OF INVENTION

In the case of laminating a plurality of substrates to transmit and receive an optical signal between a light emitting element provided on one substrate and a light receiving element provided on another substrate, it is required to position the light emitting element and the light receiving element which transmit and receive an optical signal on different substrates with high accuracy, and there may be variations in alignment accuracy on the substrate of the light emitting element or the light receiving element. In particular, in the case of mounting a light emitting element or a light receiving element on a substrate, it is required to position the light emitting element or the light receiving element with high accuracy before mounting it on the substrate.

When a light emitting element or a light receiving element is arranged on a substrate at high density, even in the case of transmitting and receiving an optical signal between a pair of light emitting element and light receiving element positioned on different substrates at high accuracy, the directivity of the light emitting element and the light receiving element is weak in some cases, and there may be a generation of a false signal transmission (crosstalk) in which an optical signal generated from one light emitting element is received by a light receiving element which should not originally receive the optical signal.

One or more embodiments of the present invention is to improve alignment accuracy of a light emitting element or a light receiving element on a substrate, suppress crosstalk of signal transmission between substrates (chips), and the like by a relatively simple production process.

In one or more embodiments of the present invention is an optical interconnection device for transmitting and receiving an optical signal between a plurality of laminated semiconductor substrates, wherein a plurality of light emitting elements or a plurality of light receiving elements arranged in one of the semiconductor substrates have pn junction parts using the semiconductor substrate as a common semiconductor layer, and one of the light emitting elements and one of the light receiving elements, which form a pair and which transmit and receive an optical signal between the different semiconductor substrates, emit and receive light at a common wavelength.

### Advantageous Effects of Invention

In one or more embodiments of the optical interconnection device having such characteristics, a plurality of light emitting elements or a plurality of light receiving elements have the respective pn junction parts using the semiconductor substrate as a common semiconductor layer and are formed in each of semiconductor substrates using lithography technics. Thus, alignment accuracy in the semiconductor substrate of the light emitting elements or the light receiving elements can be improved by a relatively simple production process. A light emitting element and a light receiving element, which form a pair and which transmit and receive an optical signal between different semiconductor substrates, emit and receive light at a common wavelength. Thus, crosstalk of signal transmission between the substrates (chips) can be suppressed.

### BRIEF DESCRIPTION OF THE DRAWINGS

FIG. 1 is an explanatory view showing the optical interconnection device according to one or more embodiments of the present invention.

FIG. 2 is an explanatory view showing a configuration example of light emitting elements and the light receiving elements arranged in different semiconductor substrates in the optical interconnection device according to one or more embodiments of the present invention.

FIG. 3(a) and FIG. 3(b) are an explanatory view showing another configuration example of light emitting elements and light receiving elements arranged in different semiconductor substrates in the optical interconnection device according to one or more embodiments of the present invention.

FIG. 4 is an explanatory view showing yet another configuration example of light emitting elements and light receiving elements arranged in different semiconductor substrates in the optical interconnection device according to one or more embodiments of the present invention.

FIG. 5 is an explanatory view showing a method for forming a light emitting element or a light receiving element formed in a semiconductor substrate in the optical interconnection device according to one or more embodiments of the present invention.

### DETAILED DESCRIPTION

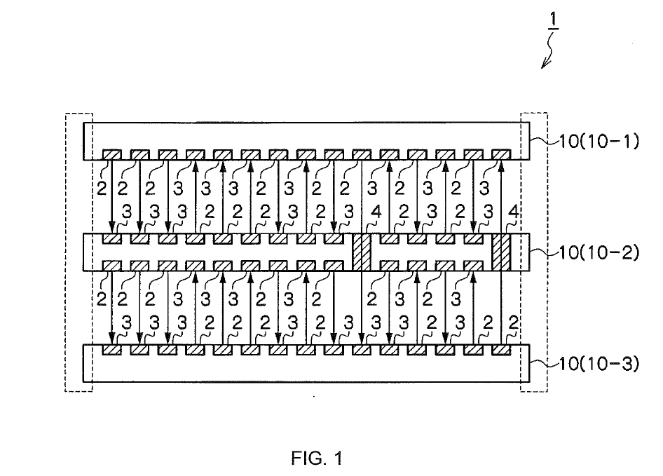

One or more embodiments of the present invention are described below with reference to the drawings. FIG. 1 is an explanatory view showing the optical interconnection device according to one or more embodiments of the present invention. An optical interconnection device 1 includes a plurality of laminated semiconductor substrates 10 (10-1, 10-2, 10-3), and an optical signal is transmitted and received among the plurality of semiconductor substrates 10 (10-1, 10-2, 10-3). Although three semiconductor substrates 10 are laminated in the example shown in FIG. 1, the number of the semiconductor substrates is not limited thereto, and it is only required that two or more semiconductor substrates 10 are laminated. A plurality of light emitting elements 2 or a plurality of light receiving elements 3 are arranged in one semiconductor substrate 10. The form of the arrangement of the light emitting elements 2 or the light receiving elements 3 is not limited to particular arrangements and includes any of arrangements such as a dot-matrix arrangement, a stripe arrangement, and a linear arrangement. The arrangement may be an arrangement of only light emitting elements 2 on one semiconductor substrate 10 and only light receiving elements 3 on another semiconductor substrate 10. Beside the light emitting elements 2 and the light receiving elements 3, a drive unit for driving the light emitting elements 2 or the light receiving elements 3, an arithmetic processing circuit (integrated circuit) which outputs a signal to the drive circuit for the light emitting elements 2, an arithmetic processing circuit (integrated circuit) which inputs the signal from the drive circuit for the light receiving elements 3, and the like can be formed or mounted on each of the semiconductor substrates 10.

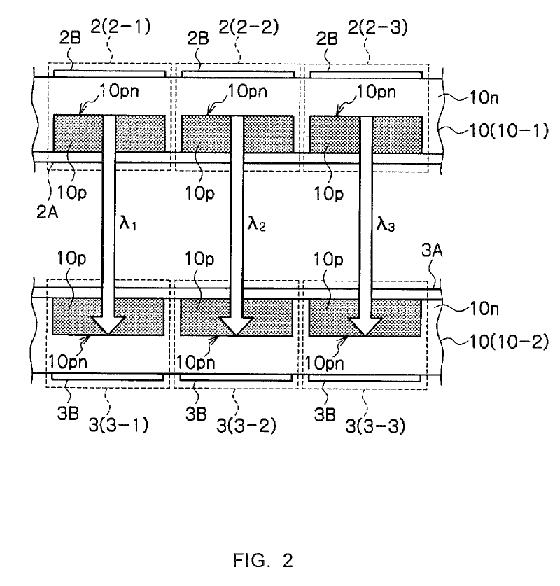

FIG. 2 is an explanatory view showing a configuration example of light emitting elements and the light receiving elements arranged in different semiconductor substrates in the optical interconnection device according to one or more embodiments of the present invention. In an optical interconnection device 1, the plurality of light emitting elements 2 (2-1, 2-2, 2-3) or the plurality of light receiving elements 3 (3-1, 3-2, 3-3) arranged in each of the semiconductor substrates (10-1, 10-2) include the respective pn junction parts 10pn using each of the semiconductor substrates 10 as a common semiconductor layer. Specifically, in each of the semiconductor substrates 10, a first semiconductor layer 10n and second semiconductor layers 10p common to the plurality of light emitting elements 2 (2-1, 2-2, 2-3) or the plurality of light receiving elements 3 (3-1, 3-2, 3-3) are formed, and pn junction parts 10pn are formed in the vicinity of the interface between the first semiconductor layer 10n and each of the second semiconductor layers 10p. As a specific example, each of the semiconductor substrates 10 is a silicon (Si) substrate (a single-crystal substrate), the first semiconductor layer 10n is an n-type Si layer obtained by doping a semiconductor substrate 10 with a Group 15 element, which is an impurity selected from, for example, arsenic (As), phosphorus (P), and antimony (Sb), and each of the second semiconductor layers 10p is a p-type semiconductor layer obtained by doping the first semiconductor layer 10n with a Group 13 element, which is an impurity selected from, for example, boron (B), aluminum (Al), and gallium (Ga).

Each of the light emitting elements 2 includes a first electrode 2A and a second electrode 2B for applying a forward voltage to each of the pn junction parts 10pn. The first electrode 2A is a transparent electrode which light can pass through, and each of the pn junction parts 10pn in each of the light emitting elements 2 functions as a light emitting part which emits light through the first electrode 2A by applying a voltage between the first electrode 2A and the second electrode 2B.

Each of the light receiving elements 3 includes a first electrode 3A and a second electrode 3B sandwiching each of the pn junction parts 10pn. The first electrode 3A is a transparent electrode which light can pass through, and when light is incident on the pn junction part 10pn via the first electrode 3A, a voltage is generated between the first electrode 3A and the second electrode 3B, and the pn junction part 10pn in the light receiving element 3 functions as a light receiving part.

Each of pairs of light emitting elements 2 (2-1, 2-2, 2-3) and light receiving elements 3 (3-1, 3-2, 3-3) which transmits and receives an optical signal between different semiconductor substrates 10 (10-1, 10-2) emits and receives light at a common wavelength. Specifically, in the case where one light emitting element 2-1 in the semiconductor substrate 10-1 and one light receiving element 3-1 in the semiconductor substrate 10-2 transmit and receive an optical signal, the light emitting element 2-1 emits light at a wavelength λ1, and the light receiving element 3-1 has a function of receiving only light at the wavelength λ1. The light at the wavelength λ1 includes light in a wavelength band having the center wavelength in the vicinity of the wavelength λ1.

Moreover, among the plurality of light emitting elements 2-1, 2-2, and 2-3 arranged in one semiconductor substrate 10-1, the light emitting elements (2-1 and 2-2 or 2-2 and 2-3) that are arranged adjacent to each other emit light at different wavelengths, and among the plurality of light receiving elements 3-1, 3-2, and 3-3 arranged in one semiconductor substrate 10-2, the light receiving elements (3-1 and 3-2 or 3-2 and 3-3) that are arranged adjacent to each other receive light at different wavelengths. That is, in the case where the light emitting elements 2-1, 2-2, and 2-3 are arranged in the semiconductor substrate 10-1 in line, and the light receiving elements 3-1, 3-2, and 3-3 corresponding to the light emitting elements 2-1, 2-2, and 2-3, respectively, are arranged in the semiconductor substrate 10-2 in line, the light emitting element 2-1 emits light at a wavelength λ1, the light receiving element 3-1 receives only light at the wavelength λ1, the light emitting element 2-2 emits light at a wavelength λ2, the light receiving element 3-2 receives only light at the wavelength λ2, the light emitting element 2-3 emits light at a wavelength λ3, and the light receiving element 3-3 receives only light at the wavelength λ3. At that time, the wavelength λ1 and the wavelength λ2 are different from each other, and the wavelength λ2 and the wavelength λ3 are different from each other, but the wavelength λ1 and the wavelength λ3 may be identical to each other.

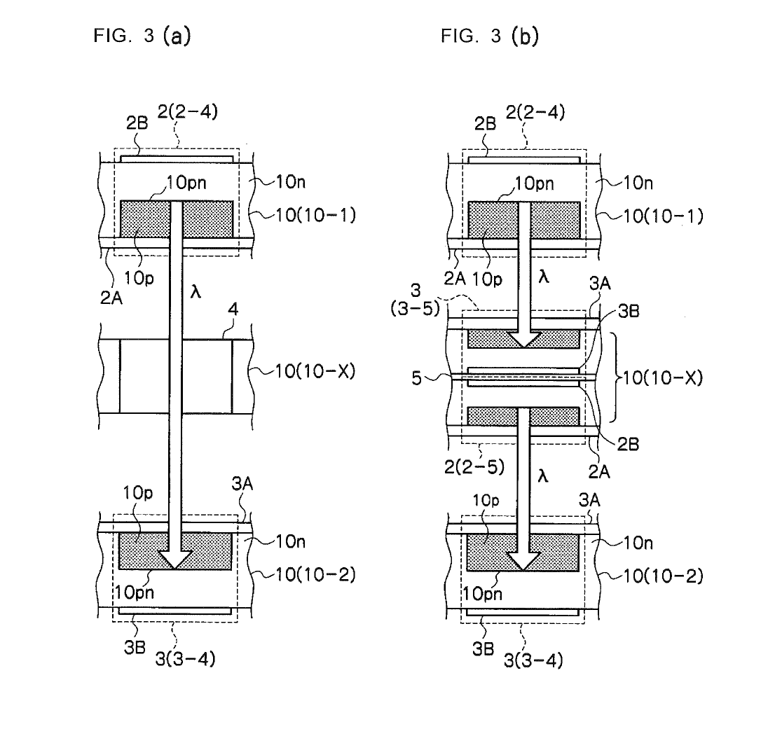

FIG. 3(a) and FIG. 3(b) are an explanatory view showing another configuration example of light emitting elements and light receiving elements arranged in different semiconductor substrates in the optical interconnection device according one or more embodiments of the present invention. The identical parts to those described in FIG. 2 are denoted by identical reference numerals, and overlapping description is omitted. FIG. 3(a) and FIG. 3(b) show the case of presenting an intermediate semiconductor substrate 10-X between a first semiconductor substrate 10-1 in which a light emitting element 2 (2-4) is arranged and a second semiconductor substrate 10-2 in which a light receiving element 3 (3-4) is arranged.

In an example shown in FIG. 3(a), a light pass through part 4 which an optical signal passes through at a wavelength λ is provided in the intermediate semiconductor substrate 10-X arranged between the light emitting element 2-4 and the light receiving element 3-4 which form a pair and which transmit and receive an optical signal between the different semiconductor substrates 10-1 and 10-2. This light pass through part 4 can be formed by a through-hole formed in the intermediate semiconductor substrate 10-X.

In an example shown in FIG. 3(b), a light receiving element 3-5 and a light emitting element 2-5 are laminated in the intermediate semiconductor substrate 10-X. The light receiving element 3-5 arranged in the intermediate semiconductor substrate 10-X receives an optical signal at a wavelength A. generated in the light emitting element 2-4 which is arranged in the first semiconductor substrate 10-1 and converted into an electrical signal, the light emitting element 2-5 laminated in the intermediate semiconductor substrate 10-X is driven by this electrical signal to emit the optical signal at the wavelength λ, and the light receiving element 3-4 arranged in the second semiconductor substrate 10-2 receives this optical signal. In this example, an insulation layer 5 is formed between second electrodes 3B and 2B in the intermediate semiconductor substrate 10-X.

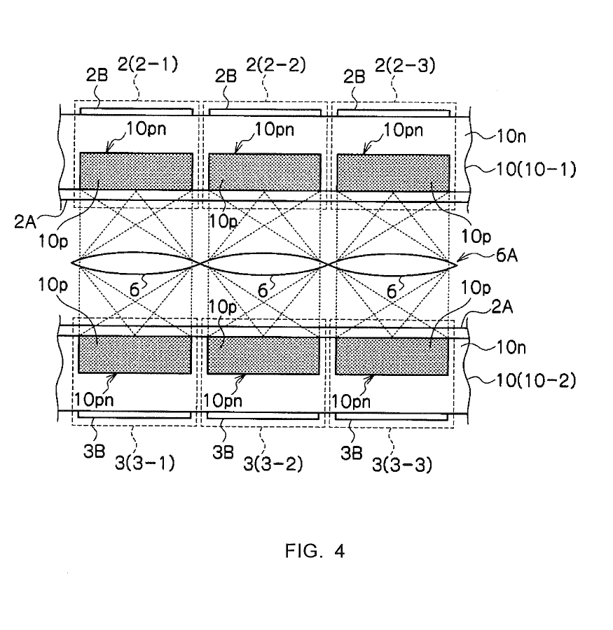

FIG. 4 is an explanatory view showing yet another configuration example of light emitting elements and light receiving elements arranged in different semiconductor substrates in the optical interconnection device according to one or more embodiments of the present invention. The identical parts to those described in FIG. 2 are denoted by identical reference numerals, and overlapping description is omitted. In FIG. 4, a lens 6 is arranged between a light emitting element 2-1 and a light receiving element 3-1 which form a pair and which transmit and receive an optical signal, and lenses 6 are arranged between the plurality of light emitting elements 2 (2-1, 2-2, 2-3) and the plurality of light receiving elements 3 (3-1, 3-2, 3-3) as a lens array 6A. By arranging such lens 6 or lens array 6A in between, light emitted at a predetermined aperture angle from the light emitting elements 2 (2-1, 2-2, 2-3) can be efficiently concentrated in the light receiving elements 3 (3-1, 3-2, 3-3).

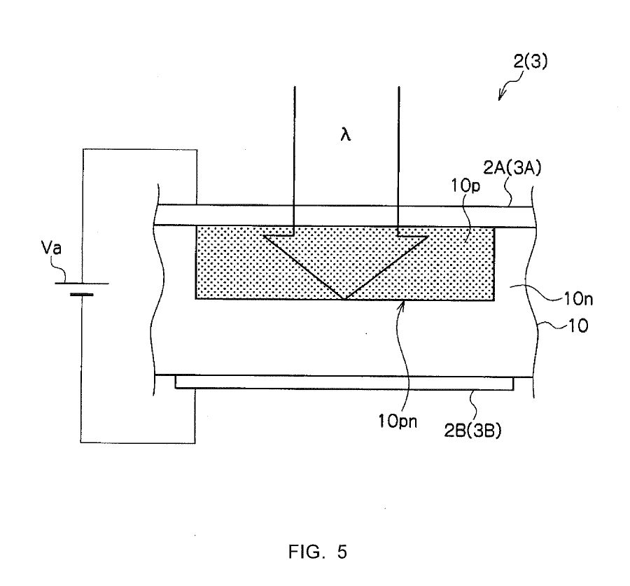

FIG. 5 is an explanatory view showing a method for forming a light emitting element or a light receiving element formed in a semiconductor substrate in the optical interconnection device according to one or more embodiments of the present invention. In a light emitting element 2 or a light receiving element 3 formed in a semiconductor substrate 10, a silicon (Si) substrate is used as a semiconductor substrate 10, the Si substrate is doped with a Group 15 element, which is an impurity selected from, for example, arsenic (As), phosphorus (P), and antimony (Sb), to form a common semiconductor layer (first semiconductor layer) 10n as an n-type Si layer, and this semiconductor layer 10n is doped with an impurity to form a pattern of a second semiconductor layer (p-type semiconductor layer) 10p.

Silicon (Si) is an indirect transition-type semiconductor and has low light emitting efficiency and cannot obtain useful light emission merely by forming a pn junction part. However, an Si substrate is subjected to annealing with the assistance of phonon to generate dressed photons in the vicinity of the pn junction part and change Si which is an indirect transition-type semiconductor to as if it is a direct transition-type semiconductor, thereby achieving high-efficiency, high-output pn junction-type light emitting or pn junction type light receiving function.

More specifically, an n-type Si layer doped with an Group 15 element, which is an impurity selected from, for example, arsenic (As), phosphorus (P), and antimony (Sb), is doped with a Group 13 element, which is an impurity selected from boron (B), aluminum (Al), and gallium (Ga), at high concentration to form a second semiconductor layer (p-type semiconductor layer) 10p. Thereafter, a first electrode 2A (3A) which is a transparent electrode and a second electrode 2B (3B) are formed so as to sandwich the pn junction part 10pn, a forward voltage Va is applied between the first electrode 2A (3A) and the second electrode 2B (3B) to apply a current to the pn junction part 10pn, and the second semiconductor layer 10p is subjected to an anneal treatment using the Joule heat caused by the current.

In the stage of diffusing the Group 13 element, which is the impurity selected from, for example, boron (B), aluminum (Al), and gallium (Ga), in the anneal treatment, the pn junction part 10pn is irradiated with light at a specific wavelength λ. By the light irradiation in the stage of the annealing, dressed photons can be generated in the vicinity of the pn junction part 10pn. When a forward voltage is applied to the pn junction part 10pn, in the vicinity of which dressed photons are generated as described above, the pn junction part 10pn emits light at the same wavelength as the wavelength A, of the light radiated in the stage of the annealing. Moreover, the pn junction part 10pn functions as a light receiving part which reacts only to light at the wavelength λ. An example of impurity doping conditions in the case of selecting boron (B) as an impurity of a Group 13 element includes a dose density: 5*10¹³/cm² and an acceleration energy at the time of injection: 700 keV.

When forming a light emitting element 2-1 and a light receiving element 3-1 that form a pair and transmit and receive an optical signal between different semiconductor substrates 10-1 and 10-2, the wavelength of light radiated in the stage of the above-mentioned anneal treatment is set to be the same as the wavelength λ. Thus, the wavelength of light emitted from the light emitting element 2-1 is specified to λ, and the wavelength of the light received from the light receiving element 3-1 also is specified to λ.

The light emitting element 2 and the light receiving element 3 have the same configuration. Thus, the one functioning as a light emitting element 2 can function as a light receiving element 3, and vice versa, the one functioning as a light receiving element 3 can function as a light emitting element 2. This switching can be optionally performed by a peripheral circuit of the optical interconnection device 1, and by this switching, the transmission path of the optical signal can be optionally changed.

In the optical interconnection device 1 according to one or more embodiments of the present invention described above, the plurality of light emitting elements 2 or the plurality of light receiving elements 3 have pn junction parts 10pn using a semiconductor substrate 10 as a common semiconductor layer and are formed in one semiconductor substrate 10 using a semiconductor lithography technics. Thus, alignment accuracy of the light emitting elements 2 or the light receiving elements 3 in the semiconductor substrate 10 can be improved by a relatively simple production process. Moreover, a light emitting element 2 and a light receiving element 3, which form a pair and which transmit and receive an optical signal between different semiconductor substrates 10, emit and receive light at a common wavelength. Thus, signal transmission crosstalk between the semiconductor substrates 10 (chips) can be suppressed.

In particular, as shown in FIG. 2, in the case where, among a plurality of light emitting elements 2-1, 2-2, and 2-3 arranged in one semiconductor substrate 10-1, the light emitting elements arranged adjacent to each other emit light at different wavelengths, and among a plurality of light receiving elements 3-1, 3-2, and 3-3 arranged in one semiconductor substrate 10-2, the light receiving elements arranged adjacent to each other receive light at different wavelengths, false signal transmission (crosstalk) in which the light receiving element 3-2 next to the light receiving element 3-1 which originally should receive an optical signal emitted from one light emitting element 2-1 receives the optical signal can be suppressed.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

1. An optical interconnection device comprising:
a plurality of light emitting elements or a plurality of light receiving elements arranged on one of semiconductor substrates having pn junction parts using the semiconductor substrate as a common semiconductor layer,
wherein the optical interconnection device transmits and receives an optical signal between a plurality of laminated semiconductor substrates, and
one of the light emitting elements and one of the light receiving elements, which form a pair and which transmit and receive an optical signal between the different semiconductor substrates, emit and receive light at a common wavelength.

2. The optical interconnection device according to claim 1,
wherein among the plurality of light emitting elements arranged in one of the semiconductor substrates, light emitting elements arranged adjacent to each other emit light at different wavelengths.

3. The optical interconnection device according to claim 1, wherein among the plurality of light receiving elements arranged in one of the semiconductor substrates, light receiving elements arranged adjacent to each other receive light at different wavelengths.

4. The optical interconnection device according to claim 1,
wherein the common semiconductor layer is an n-type Si layer, the n-type Si layer is doped with an impurity to form a p-type semiconductor layer forming the pn junction parts in the vicinity of an interface with the n-type Si layer, and
the common wavelength for each of the light emitting elements and the light receiving elements is specified by a wavelength of light radiated in a stage of diffusing the impurity in an anneal treatment.

5. The optical interconnection device according to claim 4, wherein the impurity is a material selected from Group 13 elements.

6. The optical interconnection device according to claim 5,
wherein a light pass through part which an optical signal passes through is provided in the semiconductor substrate arranged between one of the light emitting elements and one of the light receiving elements which form a pair and which transmit and receive the optical signal between the different semiconductor substrates.

7. The optical interconnection device according to claim 2,
wherein among the plurality of light receiving elements arranged in one of the semiconductor substrates, light receiving elements arranged adjacent to each other receive light at different wavelengths.
